(19) United States
(12) Patent Application Publication
(10) Pub. No.: US 2026/0182288 A1
(43) Pub. Date: Jun. 25, 2026

(54) WAFER PROCESSING APPARATUS AND WAFER PROCESSING METHOD

(71) Applicant: DISCO CORPORATION, Tokyo (JP)

(72) Inventor: Akira MIZUTANI, Tokyo (JP)

(21) Appl. No.: 19/413,365

(22) Filed: Dec. 9, 2025

(30) Foreign Application Priority Data
Dec. 19, 2024 (JP) 2024-223816
Oct. 2, 2025 (JP) 2025-166080

(51) Int. Cl. H10P 54/20; H10P 72/00

(52) U.S. Cl. CPC H10P 54/20; H10P 72/0428

(57) ABSTRACT

A wafer processing apparatus for performing processing on a bonded wafer, in which a first wafer and a second wafer are bonded, includes a holding table which holds the second wafer of the bonded wafer; a laser beam applying unit which forms a ring-shaped modified layer by positioning a condensing point of a laser beam on an inner side adjacent to a chamfered portion, which is formed at an outer periphery of the first wafer of the bonded wafer held on the holding table, and applying the laser beam; and a fluid supplying unit which supplies fluid that weakens a bonding force to an interface of the chamfered portion in which the first wafer and the second wafer are bonded.

### BACKGROUND

### 1. Technical Field

The present disclosure relates to a wafer processing apparatus and a wafer processing method for processing a bonded wafer, in which a first wafer and a second wafer are bonded.

### 2. Description of the Related Art

A wafer, on which surface a plurality of devices (e.g. ICs, LSIs) are formed by being divided along division lines, is formed to a predetermined thickness first by being ground at the rear face thereof. Then this wafer is divided into individual device chips by a dicing apparatus and a laser processing apparatus, and is used for an electronic device such as a mobile phone and a personal computer.

The outer periphery of the wafer is chamfered, hence this chamfered portion becomes a sharp knife edge when the rear surface of the wafer is ground. This knife edge causes problems of, for example, cracking that is generated from the knife edge which extends inside the wafer and damages the device, or injuries to an operator who is handling the wafer. Therefore a technique to remove the chamfered portion of the wafer has been proposed (see JP 2020-088187 A).

### SUMMARY

However the technique of bonding the first wafer and the second wafer and then grinding the rear face of the first wafer to implement a desired thickness, so as to improve the functions of the devices, has a problem, i.e., the removal of the chamfered portion from the first wafer is relatively difficult.

In other words, the bonding force of the wafers bonded by siloxane bonds or the like is so strong that even if a modified layer is formed inside the first wafer by positioning a condensing point of the laser beam, which has a wavelength that is transmissive to the wafer, on the inner side adjacent to the chamfered portion and applying the laser beam, it is difficult to remove the chamfered portion. Further, in the case of removing the region of a chamfered portion from the first wafer by cutting the region using a cutting blade, a problem arises in that the second wafer may be scratched.

With the foregoing in view, a main technical object of the present disclosure is to provide a wafer processing apparatus and a wafer processing method to solve the problem of difficulty in removing a chamfered portion, even if a modified layer is formed by positioning a condensing point of a laser beam, which has a wavelength that is transmissive to the first wafer, on the inner side adjacent to the chamfered portion of the first wafer and applying the laser beam, when the bonded wafer in which the first wafer and the second wafer are bonded is processed.

To solve the above problem, the present disclosure provides a wafer processing apparatus to perform processing on a bonded wafer in which a first wafer and a second wafer are bonded, including: a holding table which holds the second wafer of the bonded wafer; a laser beam applying unit which forms a ring-shaped modified layer by positioning a condensing point of a laser beam on an inner side adjacent to a chamfered portion, which is formed at an outer periphery of the first wafer of the bonded wafer held on the holding table, and applying the laser beam; and a fluid supplying unit which supplies fluid that weakens a bonding force to an interface of the chamfered portion in which the first wafer and the second wafer are bonded. The fluid supplying unit includes a liquid storage tank into which the chamfered portion of the bonded wafer, in which the ring-shaped modified layer is formed, is dipped so that the fluid to weaken the bonding force is infiltrated into the interface of the chambered portion.

It is preferable that a chamfered portion removal unit that removes the chamfered portion from the outer periphery of the first wafer in which the modified layer is formed, is disposed. It is also preferable that the first wafer and the second wafer are bonded by siloxane bonds of Si—O—Si. The fluid that weakens the bonding force contains at least one of water and ammonia, and the bonding force at the interface is weakened by a function of the fluid, the function changing the bonding of Si—O—Si to a bonding of Si—OH—OH—Si. It is also preferable that the water processing apparatus includes a pressurizing unit which applies pressure to the fluid infiltrated into the liquid storage tank.

The present disclosure also provides a wafer processing method of performing processing on a bonded wafer in which a first wafer and a second wafer are bonded, the method including: preparing the above mentioned wafer processing apparatus; holding the second wafer of the bonded wafer on a holding table of the wafer processing apparatus; forming a ring-shaped modified layer by positioning a condensing point of a laser beam on an inner side adjacent to a chamfered portion formed at an outer periphery of the first wafer of the bonded wafer held on the holding table, and applying the laser beam; and dipping the chamfered portion of the bonded wafer, in which the ring-shaped modified layer is formed, to supply fluid so that the fluid that weakens the bonding force is infiltrated into the interface of the chamfered portion, by using the fluid supplying unit of the wafer processing apparatus. In the supply of the fluid, the chamfered portion of the bonded wafer, in which the ring-shaped modified layer is formed, is dipped in a liquid storage tank which is disposed to surround the holding table, so that the fluid that weakens the bonding force is supplied to the interface of the chamfered portion.

It is preferable that the wafer processing method of the present disclosure further includes applying pressure to the fluid after the supply of the fluid.

The wafer processing apparatus of the present disclosure is a wafer processing apparatus performing processing on a bonded wafer in which a first wafer and a second wafer are bonded, including: a holding table which holds the second wafer of the bonded wafer; a laser beam applying unit which forms a ring-shaped modified layer by positioning a condensing point of a laser beam on an inner side adjacent to a chamfered portion, which is formed at an outer periphery of the first wafer of the bonded wafer held on the holding table, and applying the laser beam; and a fluid supplying unit which supplies fluid that weakens a bonding force to an interface of the chamfered portion in which the first wafer and the second wafer are bonded. The fluid supplying unit includes a liquid storage tank into which the chamfered portion of the bonded wafer, in which the ring-shaped modified layer is formed, is dipped so that the fluid to weaken the bonding force is infiltrated into the interface of the chamfered portion. Therefore the bonding force, in a region corresponding to the chamfered portion at the interface of the bonded wafer, is weakened, and the chamfered portion of the first wafer can be easily removed, starting from the modified layer formed in a ring shape. This solves the problem of the difficulty in removing the chamfered portion. Further, it is unnecessary to use a cutting blade to remove the chamfered portion, hence the problem of scratching the second wafer, with which the first wafer is bonded, is also solved.

The wafer processing method of the present disclosure is a wafer processing method to perform processing on a bonded wafer in which a first wafer and a second wafer are bonded. The wafer processing method includes: preparing the above mentioned wafer processing apparatus; holding the second wafer of the bonded wafer on a holding table of the wafer processing apparatus; forming a ring-shaped modified layer by positioning a condensing point of a laser beam on an inner side adjacent to a chamfered portion formed at an outer periphery of the first wafer of the bonded wafer held on the holding table, and applying the laser beam; and dipping the chamfered portion of the bonded wafer, in which the ring-shaped modified layer is formed, to supply fluid so that the fluid that weakens the bonding force is infiltrated into the interface of the chamfered portion, by using the fluid supplying unit of the wafer processing apparatus. In the supply of the fluid, the chamfered portion of the bonded wafer, in which the ring-shaped modified layer is formed, is dipped in a liquid storage tank which is disposed to surround the holding table, so that the fluid that weakens the bonding force is supplied to the interface of the chamfered portion. In the supply of the fluid, the chamfered portion of the bonded wafer, in which the ring-shaped modified layer is formed, is dipped in a liquid storage tank which is disposed to surround the holding table, so that the fluid that weakens the bonding force is supplied to the interface of the chamfered portion. Therefore the bonding force, in a region corresponding to the chamfered portion at the interface of the bonded wafer, is weakened, and the chamfered portion of the first wafer can be easily removed, starting from the modified layer formed in a ring shape. This solves the problem of the difficulty in removing the chamfered portion. Further, it is unnecessary to use a cutting blade to remove the chamfered portion, hence the problem of scratching the second wafer, with which the first wafer is bonded, is also solved.

### BRIEF DESCRIPTION OF THE DRAWINGS

FIG. 1 is a perspective view of a bonded wafer which is processed by a processing apparatus of this embodiment;

FIG. 2 is a general perspective view of a laser processing apparatus of this embodiment;

FIG. 3A is an enlarged perspective view of a fluid supplying unit disposed on the laser processing apparatus illustrated in FIG. 2, and FIG. 3B is a partially enlarged cross-sectional view of the fluid supplying unit illustrated in FIG. 3A;

FIG. 4A is a perspective view of a state where the laser processing apparatus illustrated in FIG. 2 forms a ring-shaped modified layer in the bonded wafer, and FIG. 4B is a partially enlarged cross-sectional view of the state illustrated in FIG. 4A;

FIG. 5 is a plan view of radial modified layers formed on a first wafer;

FIG. 6A is a perspective view depicting a state where a low-bonding force region is formed at an interface of the bonded wafer in fluid supplying, and FIG. 6B is a partially enlarged cross-sectional view of the state illustrated in FIG. 6A;

FIG. 7 is a perspective view depicting a state where a chamfered portion is removed from the outer periphery of the first wafer;

FIG. 8A is an enlarged perspective view of a motor and a chamfered portion removing portion of a chamfered portion removal unit attached to the laser processing apparatus illustrated in FIG. 2, FIG. 8B is a perspective view of the chamfered portion removing portion illustrated in FIG. 8A viewed from the lower side, and FIG. 8C is a conceptual diagram depicting a state where the chamfered portion is removed by the chamfered portion removal unit;

FIG. 9 is a perspective view depicting a state where grinding processing is performed on a bonded wafer after the chamfered portion is removed; and

FIG. 10A is a perspective view depicting a state where grinding processing is performed to remove the chamfered portion, and FIG. 10B is a perspective view depicting a state where grinding processing is performed along with removing the chamfered portion of the first wafer of the bonded wafer.

### DESCRIPTION OF THE PREFERRED EMBODIMENTS

Embodiments of a wafer processing apparatus and a wafer processing method, which are configured based on the present disclosure, will be described in detail with reference to the accompanying drawings.

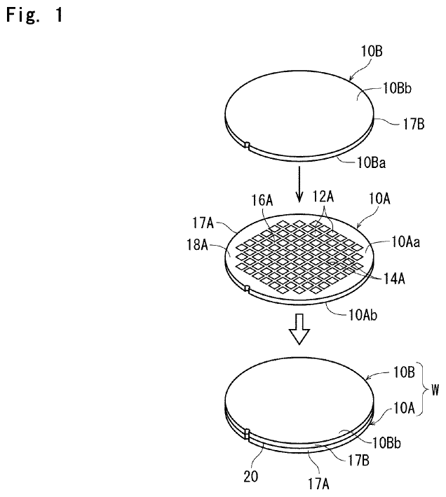

FIG. 1 illustrates an example of a bonded wafer W which is processed by the wafer processing apparatus based on the wafer processing method of this embodiment. The illustrated bonded wafer W is a bonded wafer in which a first wafer 10A and a second wafer 10B are bonded and integrated. The first wafer 10A is a silicon (Si) wafer, for example, of which diameter is 300 mm and thickness is 775 μm, and a plurality of devices 12A are formed on a front face 10Aa, so as to be divided by the division lines 14A. The first wafer 10A has the front face 10Aa and a rear face 10Ab, and includes a device region 16A which is located at the center where the devices 12A, to be used as products, are formed, and an outer peripheral surplus region 18A, where the chamfered portion 17A is formed at the outer periphery, and which surrounds the device region 16A.

The second wafer 10B has a same configuration as the first wafer 10A, where a chamfered portion 17B is formed at the outer periphery, and although illustration is omitted, the second wafer 10B is also a silicon wafer, of which diameter is 300 mm and thickness is 775 μm, and a plurality of devices, corresponding to the devices 12A on the first wafer 10A, are formed on a front face 10Ba (disposed on the lower face side in FIG. 1), so as to be divided by the division lines. The width of the chamfered portion 17A (17B) that is formed is 0.6 to 6 mm, for example, and in this embodiment, the width of the chamfered portion 17A (17B) of the bonded wafer W is 5 mm.

The first wafer 10A and the second wafer 10B of the bonded wafer W of this embodiment are integrated, for example, by bonding the front face 10Aa of the first wafer 10A and the front face 10Ba of the second wafer 10B, forming an interface 20 by siloxane bonds. The siloxane bonds is an Si—O—Si bond where silicon (Si) and oxygen (O) are bonded alternately, and the first wafer 10A and the second wafer 10B are thermally treated and bonded thereby. Hence a firm bonded state can be maintained even in a high temperature environment.

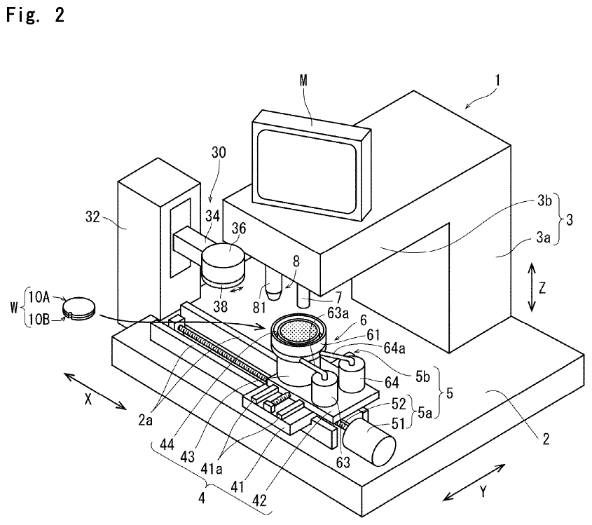

A laser processing apparatus 1 will be described with reference to FIG. 2, which is a wafer processing apparatus configured based on the present disclosure, and is a preferred example to implement the wafer processing method of the present disclosure. The illustrated laser processing apparatus 1 includes: a holding table 44 which holds the second wafer 10B of the above mentioned bonded wafer W; a laser beam applying unit 8 which forms a ring-shaped modified layer by positioning a condensing point of a laser beam on an inner side adjacent to the chamfered portion 17A, formed at an outer periphery of the first wafer 10A of the bonded wafer W held on the holding table 44, and applying the laser beam; and a fluid supplying unit 6 that supplies fluid L to weaken a bonding force to an interface 20 of the chamfered portions 17A and 17B where the first wafer 10A and the second wafer 10B are bonded.

The laser processing apparatus 1 is installed on a base 2, and includes, in addition to the above configuration: a holding unit 4 which includes the holding table 44 to hold the bonded wafer W; a moving unit 5 which moves the holding unit 4; an imaging unit 7 which images the bonded wafer W held on the holding table 44 of the holding unit 4 and executes alignment; a frame 3 which is constituted of a vertical wall portion 3a, which is vertically disposed on the side of the moving unit 5, and a horizontal wall portion 3b which extends from the upper end of the vertical wall portion 3a in the horizontal direction; a display unit M which is installed on the frame 3; a chamfered portion removal unit 30 which removes the chamfered portion 17A from the outer periphery of the first wafer 10A where the modified layer is formed; and a control unit (not illustrated).

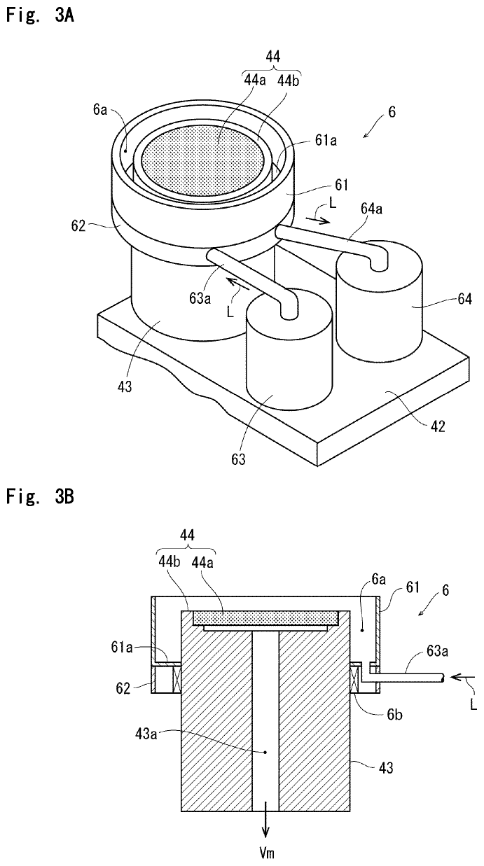

As illustrated in FIG. 2, the holding unit 4 includes: an X axis direction movable plate 41 which is a rectangular plate disposed on the base 2 to be movable in the X axis direction; a Y axis direction movable plate 42 which is a rectangular plate disposed on the X axis direction movable plate 41 to be movable in the Y axis direction; and a support 43 which is approximately cylindrical and is fixed to the upper face of the Y axis direction movable plate 42, and the holding table 44 is installed on the upper end of the support 43. As illustrated in FIG. 3A, the holding table 44 is constituted of a holding face 44a which is formed of a member having permeability, and a frame 44b which surrounds the holding face 44a and is connected to a suction unit (not illustrated). The holding table 44 is configured to be rotatable by a rotary driving unit (not illustrated). A liquid storage tank 61, which constitutes the fluid supplying unit 6, is disposed on the holding table 44. The liquid storage tank 61 is configured to surround the holding table 44 such that the upper portion is open.

Continuing the description using FIG. 2, the moving unit 5 includes an X axis moving unit 5a which moves the holding unit 4 in the X axis direction, and a Y axis moving unit 5b which moves the holding unit 4 in the Y axis direction which orthogonally intersects the X axis direction. The X axis moving unit 5a converts a rotary motion of a motor 51 into a linear motion via a ball screw 52, and transfers the linear motion to the X axis direction movable plate 41, whereby the X axis direction movable plate 41 is moved in the X axis direction along a pair of guide rails 2a and 2a disposed on the base 2 in the X axis direction. The Y axis moving unit 5b is not illustrated in detail, but has the same configuration as the X axis moving unit 5a described above. That is, the Y axis moving unit 5b transfers the rotary motion of the motor to the Y axis direction movable plate 42, whereby the Y axis direction movable plate 42 is moved along a pair of guide rails 41a and 41a disposed on the X axis direction movable plate 41 in the Y axis direction.

An optical system constituting the above mentioned laser beam applying unit 8 is housed inside the horizontal wall portion 3b of the frame 3. A condenser 81 is disposed on the lower face side of the front end of the horizontal wall portion 3b. The condenser 81 is a part of the laser beam applying unit 8, and condenses a laser beam having a wavelength that is transmissive to the first wafer 10A of the bonded wafer W, and applies the laser beam onto the bonded wafer W. An imaging unit 7 is also disposed at a position adjacent to the condenser 81 in the X axis direction. The imaging unit 7 is a camera which images the bonded wafer W held on the holding table 44 of the holding unit 4, and detects a processing position onto which the laser beam is applied.

As illustrated in FIGS. 2 and 3A, a fluid supplying pump 63, which supplies the fluid L, to weaken the bonding force at the interface 20 of the chamfered portions 17A and 17B, to the storage portion 6a of the liquid storage tank 61, and a supplying pipe 63a, which guides the fluid L discharged from the fluid supplying pump 63 to the liquid storage tank 61, are disposed adjacent to the liquid storage tank 61, which is disposed to surround the holding table 44. Further, a drain pump 64, which discharges the fluid L stored in the storage portion 6a of the liquid storage tank 61 to the outside, and a drain pipe 64a, to discharge the fluid L from the liquid storage tank 61 via the drain pump 64, are disposed adjacent to the liquid storage tank 61. This fluid L, supplied from the fluid supplying pump 63, preferably contains at least one of water and ammonia, for example, and may contain a mixed solution of water and ammonia.

The fluid supplying pump 63 and the drain pump 64 are disposed on the Y axis direction movable plate 42, and move, along with the support 43 and the holding table 44, in the X axis direction and the Y axis direction by activating the above mentioned moving unit 5. As illustrated in FIGS. 3A and 3B, an annular cover member 62 is disposed below the liquid storage tank 61, and the above mentioned supplying pipe 63a and the drain pipe 64a are connected to a bottom portion 61a of the liquid storage tank 61 via the cover member 62. The holding table 44 constituting the upper face of the support 43 is disposed so as to protrude upward from the center of the bottom portion 61a of the liquid storage tank 61, and an annular seal member 6b is disposed between the bottom portion 61a of the liquid storage tank 61 and the support 43. The holding table 44 is rotatably supported by a rotary-driving unit (not illustrated), which can rotate around the liquid storage tank 61 which is fixed to the Y axis direction movable plate 42 by a fixing unit (not illustrated). By the presence of the above mentioned seal member 6b, the leaking of fluid L from the liquid storage tank 61 is prevented, even if the holding table 44 is rotated in a state where the fluid L is stored in the storage portion 61a of the liquid storage tank 61. As illustrated in FIG. 3B, a suction passage 43a, connected to a suction unit (not illustrated), is formed inside the support 43. By activating this suction unit, a negative pressure Vm can be generated on the holding face 44a of the holding table 44.

The laser processing apparatus 1 of this embodiment generally includes the above mentioned configuration, and the laser processing apparatus 1 performs a wafer processing method of this embodiment, which will be described below. The laser processing method to be described below is a laser processing to form a ring-shaped modified layer on an inner side adjacent to a chamfered portion 17A formed at an outer periphery of the first wafer 10A of the bonded wafer W mentioned above.

In a case of performing the wafer processing method of this embodiment, preparing the laser processing apparatus 1 is performed. The laser processing apparatus 1 includes the above mentioned holding table 44, the laser beam applying unit 8, and the fluid supplying unit 6 which supplies fluid L to weaken a bonding force to an interface 20 of the chamfered portions 17A and 17B, in which the first wafer 10A and the second wafer 10B are bonded, of the bonded wafer W held on the holding table 44. The fluid supplying unit 6 includes a liquid storage tank 61 to dip the chamfered portions 17A and 17B of the bonded wafer W, in which the ring-shaped modified layer is formed, so that the fluid L, to weaken the bonding force, is infiltrated into the interface 20 of the chamfered portions 17A and 17B.

After the laser processing apparatus 1 is prepared as mentioned above, holding is performed. In the holding, the bonded wafer W is conveyed to the laser processing apparatus 1, using a conveying unit (not illustrated), and the second wafer 10B of the bonded wafer W is held on the holding table 44. In this holding, the bonded wafer W, conveyed to the laser processing apparatus 1, is placed on the above mentioned holding table 44 such that the second wafer 10B faces down, and the rear face 10Ab of the first wafer 10A faces up, and a suction unit (not illustrated) is activated to hold the bonded wafer W by suction on the holding table 44. A protective tape may be attached (not illustrated) to the rear face 10Bb side of the second wafer 10B, which is positioned on the lower side when the bonded wafer W is placed on the holding table 44. If this protective tape is attached, suction of the fluid L from the holding face 44a of the holding table 44 can be prevented, even if the fluid L is stored in the liquid storage tank 61 to dip the bonded wafer W, as mentioned later.

Then if necessary, alignment is performed using the imaging unit 7 disposed in the laser processing apparatus 1. By this alignment, the bonded wafer W is imaged and the position of the edge of the outer periphery, at which the chamfered portion 17A of the first wafer 10A is formed, and the height of the upper face of the rear face 10Ab of the first wafer 10A, are detected. Then in the region corresponding to the outer peripheral surplus region 18A on an inner side adjacent to the chamfered portion 17A, which is formed on the outer periphery of the first wafer 10A, a processing position, at which the condensing point of the laser beam LB is positioned and onto which the laser beam LB is applied, is detected. The diameter of the bonded wafer W of this embodiment is 300 mm, and the position at a 145 mm radius from the center of the first wafer 10A is detected as this processing position.

After performing the above mentioned alignment, the modified layer forming is performed to form a ring-shaped modified layer, by positioning the condensing point of the laser beam at the processing position detected by the alignment, and applying the laser beam using the above mentioned laser beam applying unit 8.

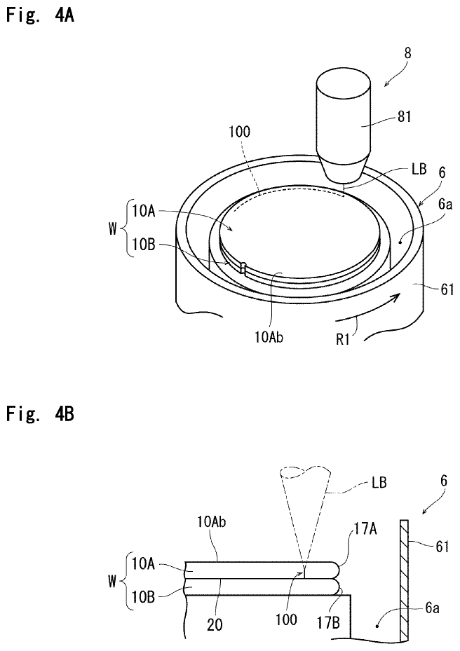

Specifically, the above mentioned moving unit 5 is activated based on the position information on the processing position detected by the above mentioned alignment, so as to move the holding table 44, and then the processing position, which is set at the outer periphery of the first wafer 10A of the bonded wafer W, is positioned immediately below the condenser 81 by the laser beam applying unit 8, as illustrated in FIG. 4A. Then as illustrated in FIGS. 4A and 4B, the laser beam applying unit 8 is activated, so that the condensing point of the laser beam LB, which has a wavelength that is transmissive to the first wafer 10A, is positioned on the inner side of the processing position on the first wafer 10A, and the laser beam LB is applied from the rear face 10Ab side of the first wafer 10A. At the same time, the holding table 44 is rotated in the arrow R1 direction indicated in FIG. 4A, so as to form a ring-shaped modified layer 100, along the inner side of the chamfered portion 17A of the first wafer 10A, and around the entire circumference.

It is preferable to form the modified layer 100 of this embodiment to have a plurality of layers in the vertical direction. For example, in the case of the modified layer 100 illustrated in FIG. 4B, the condensing point of the laser beam LB is positioned at a position which is set, such that the modified layer is formed inside the first wafer 10A on the inner side adjacent to the chamfered portion 17A, at a 650 μm depth from the rear face 10Ab near the interface 20, and the laser beam LB is applied onto the position, and at the same time, the holding table 44 is rotated to form the first layer of the ring-shaped modified layer along the chamfered portion 17A. Then while rotating the chuck table 71, the depth of the condensing point from the rear face 10Ab is raised three times: 500 μm-->350 μm-->200 μm, so that a total of four layers of ring-shaped modified layers (not illustrated) are formed in the vertical direction, along the chamfered portion 17A. A number of layers of the modified layer 100 formed by the laser beam applying unit 8 is not limited to four, as mentioned above, but may be appropriately set depending on the thickness of the first wafer 10A, the material of the first wafer 10A, the wavelength and output of the laser beam LB that is applied by the laser beam applying unit 8, and the like. The wafer processing method of this embodiment is completed thereby.

The laser processing conditions to form the above mentioned modified layer 100 are set as follows, for example.
Wavelength: 1099 nm or 1342 nm
Repetition frequency: 80 kHz
Average output power: 2.0 W
Holding table rotation speed: 60 rpm

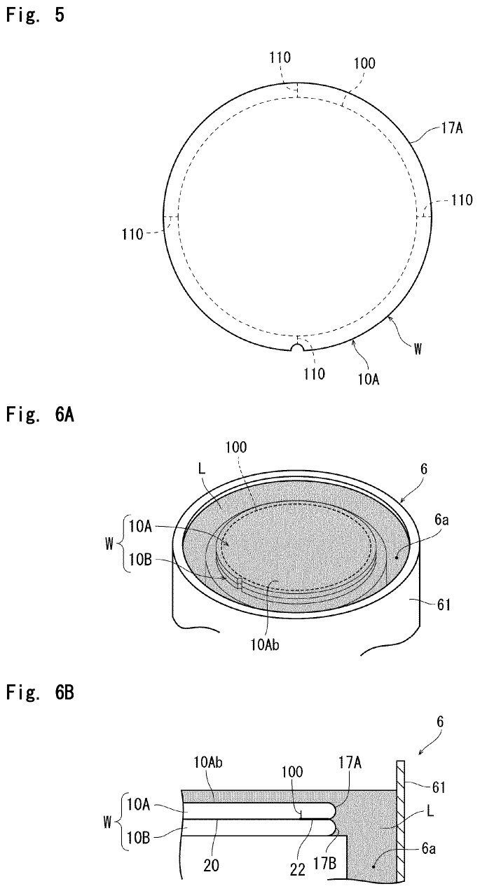

In the above mentioned modified layer forming, in addition to the modified layer 100, radial modified layers 110 may be formed, as illustrated in FIG. 5. The modified layers extend from the region where the modified layer 100 is formed, in the direction toward the outer edge where the chamfered portion 17A is formed. For example, the illustrated modified layer 110 is formed, by applying the laser beam LB under the same laser processing conditions as the case of forming the modified layer 100 mentioned above, and is formed at a plurality of locations at equal intervals (four locations in the illustrated example of this embodiment) at the outer periphery of the first wafer 10A. By forming these modified layers 110, the chamfered portions 17A are finely separated when the chamfered portion 17A is removed from the first wafer 10A, and the chamfered portion 17A can be removed more easily.

As mentioned above, after forming the ring-shaped modified layer 100 on the outer periphery of the first wafer 10A, the fluid supplying unit 6 performs the fluid supplying of dipping the chamfered portions 17A and 17B of the bonded wafer W in which the modified layer 100 is formed, so that fluid L, to weaken the bonding force, is infiltrated into the interface 20 of the chamfered portions 17A and 17B. Specifically, the fluid supplying pump 63 of the fluid supplying unit 6 is activated, and a predetermined amount of the fluid L is supplied to the storage portion 6a of the liquid storage tank 61 via the supplying pipe 63a, as illustrated in FIG. 6A. Here the drain pump 64 is stopped, hence the fluid L is not drained through the drain pipe 64a. As illustrated in FIG. 6B, the predetermined amount of fluid L refers to an amount of fluid in which the chamfered portions 17A and 17B of the bonded wafer W, held on the holding table 44, are dipped, such that the fluid L, to weaken the bonding force, is sufficiently supplied to the interface 20 of the bonded wafer W.

The interface 20 of this embodiment is bonded by the siloxane bonds (Si—O—Si bonds), and when the fluid L is supplied to the interface 20 from the side, water molecules gradually infiltrate into the interface 20, and the region where the water molecules infiltrate changes to a Si—OH—OH—Si bond. In this way, the bonding force at the interface 20 is weakened by performing the fluid supplying, and, as illustrated in FIG. 6B, an annular low-bonding force region 22, where a bonding force is lower than the siloxane bonds, is formed in the region, where the modified layer 100 is formed, from the outer periphery of the interface 20 of the bonded wafer W (outer periphery of chamfered portions 17A and 17B). Once the low-bonding force region 22 is formed as above, the above mentioned drain pump 64 is activated to drain the fluid L from the liquid storage tank 61. Thereby the wafer processing method of this embodiment is completed.

In the above mentioned embodiment, a pressurizing unit, which applies pressure to the fluid L which infiltrated into the liquid storage tank 61, may be included, although this is not illustrated. For the pressurizing unit, the storage portion 6a is configured to be sealable by a cover member or the like, which blocks the upper part of the liquid storage tank 61, for example, and an air pump is disposed so that compressed air is introduced into a space created between the fluid L and this cover member in a case where the fluid L is stored in the liquid storage tank 61. If this pressurizing unit is included, the pressurizing unit can be activated after supplying a predetermined amount of fluid L into the storage portion 6a in the above mentioned fluid supplying, and the pressure can be applied to the fluid L in the liquid storage tank 61 (i.e. pressurizing). By performing the pressurizing, infiltration of the fluid L into the interface 20 of the chamfered portions 17A and 17B of the bonded wafer W is accelerated, and the annular low-bonding force region 22, of which bonding force is weaker than the siloxane bonds, is more efficiently formed at the interface 20 of the bonded wafer W. The pressurizing unit is not limited to the above mentioned pressurizing unit, and may be implemented using a nozzle, which pressurizes the fluid L and applies a stream of the fluid from the side to the interface 20 of the chamfered portions 17A and 17B of the bonded wafer W in the liquid storage tank 61, for example. In the case of disposing the nozzle, it is not necessary to make the liquid storage tank 61 a sealed structure, but it is preferable to eject the fluid L to the bonded wafer W through the nozzle throughout the entire periphery by rotating the holding table 44 using the above mentioned rotary-driven unit, if the fluid L is ejected through the nozzle to the bonded wafer W.

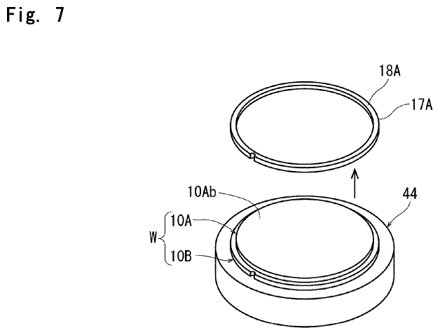

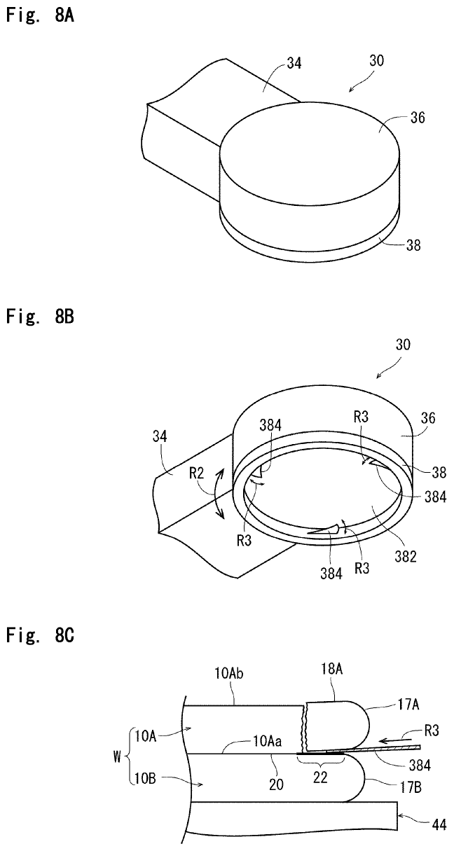

After the above mentioned wafer processing method is performed using the laser processing apparatus 1, so as to form the modified layer 100 at the outer periphery of the first wafer 10A and form the low-bonding force region 22 at the outer periphery of the interface 20 of the bonded wafer W, the chamfered portion removing can be performed, where the chamfered portion 17A, including the outer peripheral surplus region 18A, is removed from the outer periphery of the first wafer 10A, as illustrated in FIG. 7. In the bonded wafer W, not only the modified layer 100 but also the low-bonding force region 22 is formed on the first wafer 10A, hence the chamfered portion 17A can easily be removed from the first wafer 10A by simply applying the external force. The laser processing apparatus 1 of this embodiment includes the chamfered portion removal unit 30, as illustrated in FIG. 2 and FIGS. 8A to 8C, and can remove the chamfered portion 17A using this chamfered portion removal unit 30.

As illustrated in FIG. 2, the chamfered portion removal unit 30 includes: a casing 32 which extends upward from the edges of the guide rails 2a and 2a on the base 2; and an arm 34 which is elevatably supported by the casing 32 and extends in the X axis direction. The casing 32 includes an elevating unit (not illustrated) which moves the arm 34 up and down. At the front end of the arm 34, a motor 36 is disposed, and the chamfered portion removing portion 38 is connected to the lower face of the motor 36 so as to be rotary-driven by the motor 36 around the shaft line, which extends in the vertical direction.

FIG. 8A is an enlarged view of the motor 36 and a chamfered portion removing portion 38 of the chamfered portion removal unit 30, and FIG. 8B is a view of the chamfered portion removing portion 38 illustrated in FIG. 8A viewed obliquely from the lower side. As illustrated in FIG. 8B, the chamfered portion removing portion 38 is configured to be ring-shaped, and a plurality of blades 384, to remove the above mentioned chamfered portion 17A of the first wafer 10A, are disposed on the inner side face of this ring-shaped chamfered portion removing portion 38. These blades 384 are thin razor-like blades, and protrude in the inner direction as indicated by the arrow R3 in FIG. 8B, or are housed inside the chamfered portion removing portion 38, by the chamfered portion removing portion 38 that is driven and rotated forward or backward, by the motor 36 as indicated by the arrow R2 in FIG. 8B.

As described above, the modified layers 100 is formed in the outer peripheral surplus region 18A of the first wafer 10A, and then to remove the chamfered portion 17A, the X axis moving unit 5a and the Y axis moving unit 5b are activated, so as to position the holding table 44 holding the bonded wafer W to an area below the chamfered portion removing portion 38. Then the above mentioned arm 34 is lowered such that the lower face 382 of the chamfered portion removing portion 38, illustrated in FIG. 8B, is contacted with the rear face 10Ab of the first wafer 10A of the bonded wafer W. Then the chamfered portion removing portion 38 is activated using the motor 36 of the chamfered portion removal unit 30, so that the above mentioned blades 384 protrude inward, as indicated by the arrow R3 in FIG. 8C. Thereby the blades 384 can enter the low-bonding force region 22 formed at the interface 20 of the bonded wafer W, and the outer peripheral surplus region 18A, including the chamfered portion 17A, can be broken off, starting from the above mentioned modified layer 100, by rotating the holding table 44.

As mentioned above, after the chamfered portion 17A is broken off from the first wafer 10A, the motor 36 is activated to house the blades 384 in the chamfered portion removing portion 38, and to elevate the arm 34 of the chamfered portion removal unit 30. Then the chamfered portion 17A is removed from the first wafer 10A of the bonded wafer W. Once the chamfered portion 17A of the first wafer 10A of the bonded wafer W is removed like this, grinding is performed if necessary, to grind the rear face 10Ab of the first wafer 10A, to have a desired thickness.

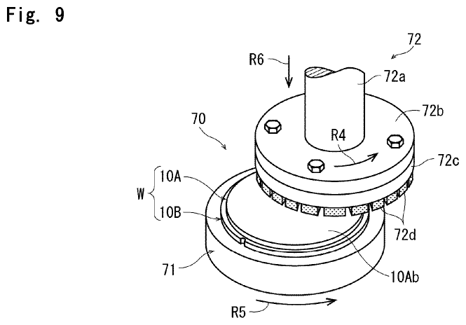

In the case of performing grinding, the above mentioned bonded wafer W, after removing the chamfered portion 17A, is conveyed to a grinding apparatus 70 (of which a part is illustrated) in FIG. 9. As illustrated in FIG. 9, the grinding apparatus 70 includes a grinding unit 72 which grinds and thins the bonded wafer W held on the chuck table 71 by suction. The grinding unit 72 includes: a rotation spindle 72a which is rotated by a rotary-driven mechanism (not illustrated); a wheel mount 72b which is attached to the bottom end of the rotation spindle 72a; and a grind wheel 72c which is attached to the lower face of the wheel mount 72b. A plurality of grinding stones 72d are disposed in a ring shape on the lower face of the grind wheel 72c.

When the bonded wafer W, conveyed to the grinding apparatus 70, is placed on the chuck table 71 with the second wafer 10B side down, as illustrated in FIG. 9, it is held thereon by suction using a suction unit (not illustrated). Then while rotating the rotation spindle 72a of the grinding unit 72 at 6000 rpm, for example, in the arrow R4 direction, as indicated in FIG. 9, the chuck table 71 is rotated at 300 rpm, for example, in the arrow R5 direction. Then while supplying grinding water onto the rear face 10Ab of the first wafer 10A using a grinding water supplying unit (not illustrated), the grinding stones 72d are contacted with the rear face 10Ab of the first wafer 10A by activating a grinding feed unit (not illustrated), and the grind wheel 72c is operated for grinding downward in the arrow R6 direction at a 1.0 μm/sec. grinding feed speed, for example. Here the grinding is advanced while measuring the thickness of the bonded wafer W using a contact type or non-contact type measuring gauge (not illustrated), so as to thin the bonded wafer W to a desired thickness.

Once a predetermined amount of grinding is performed from the rear face 10Ab of the first wafer 10A and the bonded wafer W is formed to a desired thickness, the grinding unit 72 is stopped and retracted upward, and the grinding is completed. After the grinding is completed, the cleaning and drying processing and the like (details omitted here) are performed.

According to the laser processing apparatus 1 and the wafer processing method of this embodiment described above, the ring-shaped modified layer 100 is formed in the modified layer forming, and the low-bonding force region 22, in which the bonding force is weakened, is formed at the outer periphery of the interface 20 of the bonded wafer W which is bonded by the siloxane bonds. Therefore the chamfered portion 17A of the first wafer 10A can be easily removed, starting from the modified layer 100 formed in a ring shape, and the problem of difficulty in removing the chamfered portion 17A is solved. Further, it is not necessary to remove the chamfered portion 17A using a cutting blade, that is, the problem of scratching the second wafer 10B, with which the first wafer 10A is bonded, is also solved.

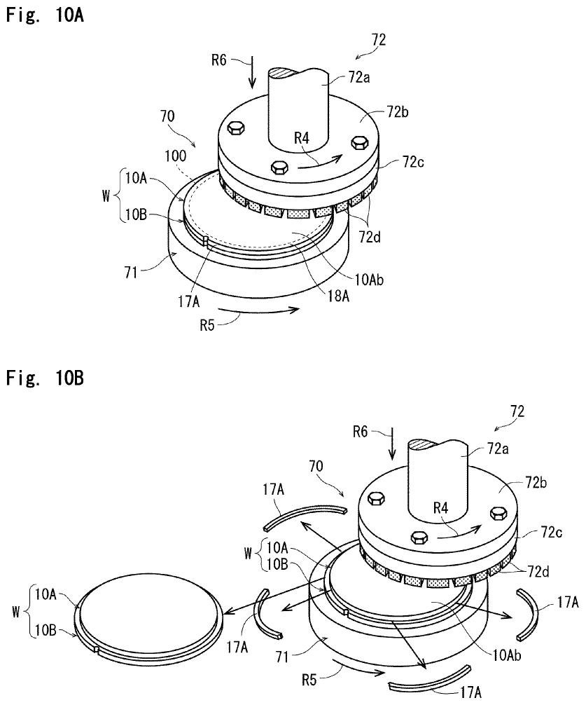

The present disclosure is not limited to the above embodiment. In the laser processing apparatus 1 of the above embodiment, the chamfered portion removal unit 30 is disposed, but this chamfered portion removal unit 30 may not be included in the laser processing apparatus 1. In the case of not including the chamfered portion removal unit 30, a chamfered portion removing may be performed, where the chamfered portion 17A is removed by supplying an external force to the bonded wafer W, by performing grinding on the rear face 10Ab of the first wafer 10 of the bonded wafer W, for example. Specifically, after forming the above mentioned modified layer 100 on the first wafer 10A of the bonded wafer W, the bonded wafer W is conveyed to the above mentioned grinding apparatus 70, as illustrated in FIG. 10A, and is held on the chuck table 71 by suction, with the second wafer 10B side facing down and the rear face 10Ab of the first wafer 10A facing up.

Then while rotating the rotation spindle 72a of the grinding unit 72 at 6000 rpm, for example, in the arrow R4 direction indicated in FIG. 10A, the chuck table 71 is rotated at 300 rpm, for example, in the arrow R5 direction. Then while supplying grinding water onto the rear face 10Ab of the first wafer 10A using a grinding water supplying unit (not illustrated), the grinding stones 72d are contacted with the rear face 10Ab of the first wafer 10A by activating the grinding feed unit (not illustrated), and the grind wheel 72c is operated for grinding downward in the arrow R6 direction at a 1.0 μm/sec. grinding feed speed, for example. Thereby an external force is applied to the rear face 10Ab of the first wafer 10A, and the outer peripheral surplus region 18A, including the chamfered portion 17A, is removed, starting from the modified layer 100. Here it is preferable that the radial modified layers 110 have been formed, as mentioned above, so that the chamfered portion 17A is appropriately divided at the outer periphery, starting from the radial modified layers 110, and is removed from the first wafer 10A easily. In the case of grinding the rear face 10Ab of the first wafer 10A of the bonded wafer W using the grinding apparatus 70, rough grinding is performed first using grinding stones for rough grinding, which are appropriate for rough grinding, and the chamfered portion 17A is removed starting from the modified layers 100 and 110, and the rough grinding is continued until the bonded wafer W reaches a predetermined thickness. Then finish grinding is performed on the rear face 10Ab of the first wafer 10A using grinding stones for finish grinding, which are appropriate for finish grinding.

As described above, when a predetermined amount of grinding of the rear face 10Ab of the first wafer 10A is performed and the bonded wafer W reaches a predetermined thickness, the grinding unit 72 is stopped and retracted upward. Thereby the grinding is completed, and the bonded wafer W, having a predetermined thickness, from which the chamfered portion 17A has been removed, can be obtained, as illustrated in the left side of FIG. 10B. Once the grinding is completed, cleaning and drying processing and the like (details omitted here) are performed. In this way, just like the above mentioned embodiment, the chamfered portion 17A of the first wafer 10A can be easily removed, starting from the modified layer 100 formed in a ring shape, using the grinding apparatus 70, and the problem of the difficulty in removing the chamfered portion 17A is solved. Further, it is not necessary to remove the chamfered portion 17A using a cutting blade, that is, the problem of scratching the second wafer 10B, to which the first wafer 10A is bonded, is also solved.

In the bonded wafer W described above, the first wafer 10A and the second wafer 10B are bonded by the siloxane bonds, but the bonded wafer processed by the wafer processing apparatus and the wafer processing method of the present disclosure is not limited to the wafer bonded by the siloxane bonds. For example, the bonded wafer may be formed by bonding the first wafer 10A and the second wafer 10B by an SiCN bond (nitride bond), or by a TEOS bond, in which tetraethyl orthosilicate molecules are transformed to have an Si—O—Si bond, or by a ThOx bond based on silicon oxide film (SiO₂) formed by oxidizing the surface of the silicon wafer by heating in an oxygen atmosphere. The bonding force can be weakened by the above mentioned fluid L, regardless what bonding is used. The wafer processing apparatus and the wafer processing method of the present disclosure are applicable also to the bonded wafer W bonded by performing O₂ plasma treatment or N₂ plasma treatment as a pretreatment of the bonding surface on which the interface 20 is formed.

### REFERENCE SIGNS LIST

1 Laser processing apparatus
2 Base
3 Frame
4 Holding unit
41 X axis direction movable plate
42 Y axis direction movable plate
43 Support
44 Holding table
44a Holding surface
44b Frame
5 Moving unit
5a X axis moving unit
5b Y axis moving unit
6 Fluid supplying unit
61 Liquid storage tank
62 Cover member
63 Fluid supplying pump
64 Drain pump
7 Imaging unit
8 Laser beam applying unit
81 Condenser
10A First wafer
10Aa Front face
10Ab Rear face
12A Device
14A Division line
16A Device region
17A Chamfered portion
18A Outer peripheral surplus region
10B Second wafer
17B Chamfered portion
20 Interface
22 Low bonding force region
30 Chamfered portion removal unit
32 Casing
34 Arm
36 Motor
38 Chamfered portion removing portion
382 Lower face
384 Blade
70 Grinding apparatus
71 Chuck table
72 Grinding unit
72d Grinding stones

What is claimed is:

1. A wafer processing apparatus performing processing on a bonded wafer in which a first wafer and a second wafer are bonded, the wafer processing apparatus comprising:
a holding table configured to hold the second wafer of the bonded wafer;
a laser beam applying unit configured to form a ring-shaped modified layer by positioning a condensing point of a laser beam on an inner side adjacent to a chamfered portion, which is formed at an outer periphery of the first wafer of the bonded wafer held on the holding table, and applying the laser beam; and
a fluid supplying unit configured to supply fluid that weakens a bonding force to an interface of the chamfered portion in which the first wafer and the second wafer are bonded, wherein
the fluid supplying unit includes a liquid storage tank into which the chamfered portion of the bonded wafer, in which the ring-shaped modified layer is formed, is dipped so that the fluid to weaken the bonding force is infiltrated into the interface of the chamfered portion.

2. The wafer processing apparatus of claim 1, wherein
a chamfered portion removal unit that removes the chamfered portion from the outer periphery of the first wafer, in which the modified layer is formed, is disposed.

3. The wafer processing apparatus of claim 1, wherein
the first wafer and the second wafer are bonded by siloxane bonding of Si—O—Si,
the fluid that weakens the bonding force contains at least one of water and ammonia, and
the bonding force at the interface is weakened by a function of the fluid, the function changing the bonding of Si—O—Si to the bonding of Si—OH—OH—Si.

4. The wafer processing apparatus of claim 1, further comprising a pressurizing unit configured to apply pressure to the fluid infiltrated into the liquid storage tank.

5. A wafer processing method of performing processing on a bonded wafer in which a first wafer and a second wafer are bonded, the method comprising:
preparing the wafer processing apparatus of claim 1;
holding the second wafer of the bonded wafer on a holding table of the wafer processing apparatus;
forming a ring-shaped modified layer by positioning a condensing point of a laser beam on an inner side adjacent to a chamfered portion formed at an outer periphery of the first wafer of the bonded wafer held on the holding table, and applying the laser beam, and
dipping the chamfered portion of the bonded wafer, in which the ring-shaped modified layer is formed, to supply fluid, so that the fluid that weakens the bonding force is infiltrated into the interface of the chamfered portion, by using the fluid supplying unit of the wafer processing apparatus, wherein
in the supply of the fluid, the chamfered portion of the bonded wafer in which the ring-shaped modified layer is formed is dipped in a liquid storage tank which is disposed to surround the holding table, so that the fluid that weakens the bonding force is supplied to the interface of the chamfered portion.

6. The wafer processing method of claim 5 further comprising applying pressure to the fluid after the supply of the fluid.
